(19) United States
(12) Patent Application Publication
(10) Pub. No.: US 2010/0266419 A1
(43) Pub. Date: Oct. 21, 2010

(54) ENGINE COMPONENT FOR A GAS TURBINE

(75) Inventors: Ulf Reinmöller, Hamburg (DE); Christian Siry, Hamburg (DE)

Correspondence Address: Casimir Jones, S.C., 2275 DEMING WAY, SUITE 310, MIDDLETON, WI, 53562, US

(73) Assignee: LUFTHANSA TECHNIK AG, Hamburg (DE)

(21) Appl. No.: 12/675,800

(22) PCT Filed: Aug. 29, 2008
(86) PCT No.: PCT/EP2008/007104

§ 371 Date: Mar. 1, 2010

(30) Foreign Application Priority Data
Sep. 5, 2007 (DE) 102007042124.0

(51) Int. Cl. F01D 5/14; B05D 7/00; C23C 16/50

(52) U.S. Cl. 416/241 R; 427/140; 427/294; 427/577

(57) ABSTRACT

The object of the invention is an engine component for arrangement in the gas flow of a gas turbine. According to the invention, at least one part of the surface of said component subjected to the gas flow in operation comprises a modified amorphous carbon layer containing hydrogen that is applied using a vacuum coating technique.

The invention relates to an engine component for arrangement in the gas flow of a gas turbine. Engine components of gas turbines, such as jet engines for aircraft, have a defined shaping which is adapted to the respective intended use in the gas flow of the turbine. The shaping of the turbine blades or vanes in the compressor stage and turbine stage of a jet engine, in particular, is crucial to achieving a high degree of efficiency of the engine.

During operation of a gas turbine, foreign bodies such as sand or ice which are sucked in with the air flow result in erosion on the engine components, and this changes the intended shape and/or surface quality and can therefore impair the degree of efficiency. Furthermore, impurities and/or combustion residues introduced together with the air flow can lead to deposits on the surface of engine components such as turbine blades or vanes, and these likewise change the gas flow at these components and therefore impair the degree of efficiency. The maximum service life of a gas turbine is reduced by such erosion and/or soiling.

The use of a high-pressure water jet to clean jet engines is known from evident prior use. Furthermore, various coatings of metallic turbine blades or vanes are known, and are primarily intended to increase the thermal stability thereof.

The invention is based on the object of providing an engine component of the type mentioned in the introduction which has improved resistance to soiling together with good wear resistance.

According to the invention, the object is achieved in that at least part of the surface of the engine component, which is exposed to the gas flow during operation, has a modified, hydrogen-containing amorphous carbon layer or coating which is applied by means of a vacuum coating technique.

Firstly, it is necessary to explain some terms used within the context of the invention.

An engine component for arrangement in the gas flow of a gas turbine denotes any component which, when installed as intended, is exposed to a gas flow over at least part of its surface during operation. This may be the gas flow in the compressor part, in the combustion chamber or in the turbine part downstream of the combustion chamber in such a gas turbine.

The invention provides that at least part of the surface of such an engine component (preferably a part of the surface exposed to the gas flow during operation) has a modified, hydrogen-containing amorphous carbon layer which is applied by means of a vacuum coating technique. Within the context of the present patent application, the term “modified, hydrogen-containing amorphous carbon layer” is used in the manner defined in VDI Guideline 2840, Issue November 2005. Carbon layers such as these are applied by a vacuum coating technique. This preferably takes place at coating temperatures of room temperature to about 300° C.

According to the above-mentioned VDI Guideline, the amorphous carbon layers are subdivided into seven types of layer denoted by the abbreviation a-C (a: amorphous, C: carbon). The group of amorphous carbon layers can also be referred to as Diamond Like Carbon (DLC). Of the seven different amorphous types of carbon layer, four contain hydrogen (a-C:H) and therefore form part of the present invention.

The invention has recognized that such a surface modification makes it possible to reduce the tendency of the surface of engine components to erode, and simultaneously the so-called anti-adhesive effect of such a modified carbon layer reduces the tendency of said surface to become soiled.

Within the context of the invention, the hydrogen-containing amorphous carbon layer is particularly preferably modified with a non-metal, e.g. silicon, oxygen, nitrogen, fluorine, boron or mixtures of these non-metals. The modified, hydrogen-containing amorphous carbon layer particularly preferably comprises a-C:H:Si and/or a-C:H:Si:O. Accordingly, it is modified either with silicon or with a combination of silicon and oxygen. Such a particularly preferred carbon layer is denoted by the layer number 2.7 in table 1 of VDI Guideline 2840.

The hardness of an engine component coated according to the invention is preferably at least 5 GPa, more preferably at least 7 GPa and further preferably at least 10 GPa. Typical hardness ranges for an a-C:H:Si:O layer may be, for example, between 7 and 9 GPa, for an a-C:H:Si layer between 10 and 15 GPa. Typical upper limits for the hardness are 30, 25, 20 and 15 GPa. The hardness is preferably measured as HV30 according to DIN EN ISO 14577-1.

In a preferred embodiment of the invention, the modified carbon layer has a degree of wear of less than (m³/Nm)·10⁻¹⁵, preferably less than 30 (m³/Nm)·10⁻¹⁵ and further preferably less than 20 (m³/Nm)·10⁻¹⁵.

The erosion resistance can be determined on the basis of a rotary wear test. This involves the measurement of material abrasion by a rotating sphere or roller which rubs against the surface. The wear volume can be calculated from the pressing pressure, geometries of the sphere or roller and the wear track. The standard which is relevant for this is ASTM G 99. According to the invention, the modified, hydrogen-containing amorphous carbon layer has a preferred degree of wear of less than 40 (m³/Nm)·10⁻¹⁵. Further preference is given to wear volumes of less than 30 (m³/Nm)·10⁻¹⁵ or of less than 20 (m/Nm)·10⁻¹⁵.

An engine component coated according to the invention preferably has a low surface energy. This low surface energy means that impurities do not adhere to the surface, or adhere thereto to a minor extent. As a result, optimum flow conditions are maintained in the gas turbine over a longer service life; a correspondingly slower drop in the Exhaust Gas Temperature (EGT) occurs. Since a high degree of efficiency is thereby retained over a longer period of time, the Time on Wing (TOW) of jet engines can be extended.

Preferred upper limits for the surface energy are 50, 45, 40, 35, 32, 28 and 24 mN/m. Typical surface energy ranges according to the invention are, for example, 30 to 35 mN/m for an a-C:H:Si coating and 22 to 26 mN/m for an a-C:H:Si:O coating.

The thermal stability of a coating according to the invention can preferably be in the range of 400 to 500° C.

Within the context of the invention, the modified, hydrogen-containing amorphous carbon layer can be applied directly to the substrate material of the engine component or else be the topmost layer of a plurality of layers.

The carbon layer according to the invention is applied by means of a vacuum coating technique, in which the coating material is firstly converted into the gas phase and then deposited on the substrate. The vacuum coating technique is preferably selected from the group consisting of physical vapor deposition (PVD), chemical vapor deposition (CVD), plasma-assisted physical vapor deposition (PA-PVD) and plasma-assisted chemical vapor deposition (PA-CVD) or a combination thereof.

The coating according to the invention is preferably produced by a combination of PVD and PA-CVD.

The layer thickness of the modified, hydrogen-containing amorphous carbon layer is preferably between 2 μm and 10 μm, further preferably between 3 μm and 7 μm. By way of example, it can be about 5 μm.

The engine component according to the invention is particularly preferably a turbine blade or vane since this is exposed to a particular extent to soiling and wear and, in addition, a change to the contour or to the flow profile can contribute decisively to impairment of the degree of efficiency during operation of a jet engine. This is preferably a turbine blade or vane in the compressor or compressor part of the engine.

The invention also relates to a jet engine for use in aircraft, which has one or more engine components according to the invention.

The invention also relates to a process for coating an engine component, in which process a vacuum coating process is used to apply a modified, hydrogen-containing amorphous carbon layer. The engine component is intended to be arranged in the gas flow of a gas turbine. The process according to the invention can be employed for the reconstruction of such engine components. A further aspect of the invention is to use the process according to the invention to retroactively provide new parts with a corresponding coating, and thus finish them, outside the actual production process.

Advantageous embodiments of the process are described in dependent claims 12 to 19. The process according to the invention makes it possible to produce turbine components which are particularly resistant to soiling and are therefore also less susceptible to wear.

The invention also relates to a process for repairing an engine component which is intended to be arranged in the gas flow of a gas turbine. The process comprises the following steps:
a) providing an engine component having wear phenomena;
b) working up the engine component in order to eliminate or reduce the wear phenomena;
c) applying a modified, hydrogen-containing amorphous carbon layer as claimed in one of claims 11 to 18 to at least part of the surface of the engine component, which is exposed to the gas flow during operation.

Engine components such as turbine blades or vanes are regularly refurbished after a wear limit has been reached. Such refurbishment can comprise the mechanical and/or chemical removal of contamination residues and the levelling-out of material removal caused by erosion by means of appropriate machining (e.g. material-removing machining) or by means of renewed application of material, e.g. the welding on of blade or vane material. The invention encompasses all of this by the expression “working up the engine component in order to eliminate or reduce the wear phenomena”.

The invention provides that this working up is followed by the application of a modified, hydrogen-containing amorphous carbon layer according to the invention. Such a refurbished engine component may then possibly have a longer service life than the new part which is not coated according to the invention.

In the case of engine blades or vanes, it can furthermore be provided to eliminate the erosion not only by simple deburring but also by providing the engine blades or vanes with an optimized shape. Simple levelling out of uneven sections on the surface of the engine blades or vanes means that the shape of this surface deviates from the ideal shape, and the optimum circumfluence of the blade or vane profile is disrupted. Therefore, it may be advantageous to change the contour of the blade or vane profile even in regions which are not affected by erosion, in order to thereby ensure better circumfluence of the engine blade or vane. Within the context of the invention, the engine component may be worked up in an automated manner, for example by means of suitable handling robots.

The invention is described by way of example below with reference to the appended drawing and on the basis of an advantageous embodiment. In the drawing:

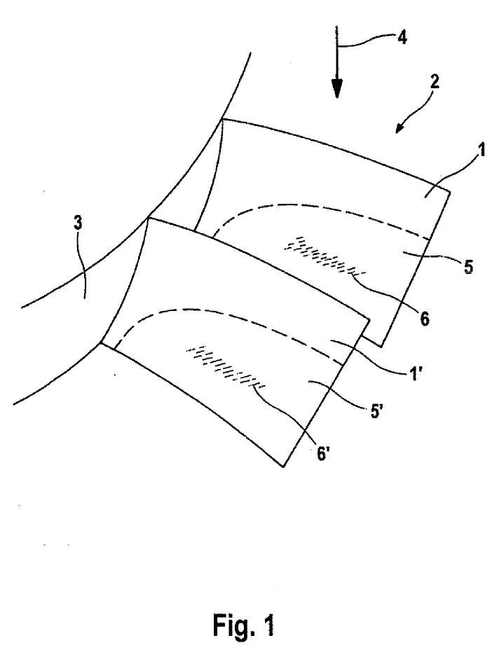

FIG. 1 shows an exemplary arrangement of two engine blades or vanes, according to the invention, of a compressor stage.

In FIG. 1, two engine blades or vanes 1, 1′, according to the invention, of a compressor stage 2 are fitted on a rotor 3 (only indicated in the drawing). Engine blades or vanes are generally provided over the entire rotor 3. For reasons of clarity, however, the illustration is restricted to two exemplary engine blades or vanes 1, 1′. The direction in which the gas flow flows over the compressor stage 2 shown is indicated by the arrow 4.

In the regions 5, 5′ delimited by the dashed border, the engine blades or vanes 1, 1′ are provided with a modified, hydrogen-containing amorphous carbon layer. These regions 5, 5′ comprise exactly those points at which foreign substances are worn off if the engine blades or vanes are not coated. Corresponding contamination is indicated by the hatched areas 6, 6′. These contaminations 6, 6′ no longer occur on account of the coating 5, 5′ according to the invention.

The exemplary embodiment described here concerns an engine blade or vane of a rotor. The invention can equally be applied, for example, to engine blades or vanes of guide wheels or the like. By way of example, the components may be used in a high pressure compressor (HPC) or low pressure compressor (LPC). It is also possible to coat the hub instead of the actual engine blade, for example. Corresponding engine components can be arranged in the primary and secondary circuits. The stator vanes may be so-called fixed vanes or variable vanes (rotatably mounted stator vanes). This can involve so-called individual vanes or cluster vanes.

It is also possible to coat components of the fan and, for example, of the low pressure turbine (LPT).

1-22. (canceled)

23. An engine component for arrangement in the gas flow of a gas turbine, characterized in that at least part of the surface of said component, which is exposed to the gas flow during operation, has a modified, hydrogen-containing amorphous carbon layer which is applied by a vacuum coating technique.

24. The engine component of claim 23, wherein the hydrogen-containing amorphous carbon layer is modified with at least one non-metal.

25. The engine component of claim 23, wherein the modified, hydrogen-containing amorphous carbon layer comprises a-C:H:Si and/or a-C:H:Si:O.

26. The engine component of claim 23, wherein the modified, hydrogen-containing amorphous carbon layer has a hardness of at least 5 GPa.

27. The engine component of claim 26, wherein the modified, hydrogen-containing amorphous carbon layer has a hardness of at least 7 GPa.

28. The engine component of claim 27, wherein the modified, hydrogen-containing amorphous carbon layer has a hardness of at least 10 GPa.

29. The engine component of claim 23, wherein the modified, hydrogen-containing amorphous carbon layer has a degree of wear of less than 40 (m³/Nm)·10⁻¹⁵.

30. The engine component of claim 29, wherein the degree of wear is less than 30 (m³/Nm)·10⁻¹⁵.

31. The engine component of claim 30, wherein the degree of wear is less than 20 (m³/Nm)·10⁻¹⁵.

32. The engine component of claim 23, wherein the modified, hydrogen-containing amorphous carbon layer has a surface energy of at most 32 mN/m.

33. The engine component of claim 32, wherein said surface energy is at most 28 mN/m.

34. The engine component of claim 33, wherein said surface energy is at most 24 mN/m.

35. The engine component of claim 23, wherein the vacuum coating technique is selected from the group consisting of physical vapor deposition (PVD), chemical vapor deposition (CVD), plasma-assisted physical vapor deposition (PA-PVD) and plasma-assisted chemical vapor deposition (PA-CVD) or a combination thereof.

36. The engine component of claim 23, wherein the layer thickness of the modified, hydrogen-containing amorphous carbon layer is 2 μm to 10 μm.

37. The engine component of claim 23, wherein said layer thickness of the modified, hydrogen-containing amorphous carbon layer is 3 μm to 7 μm.

38. The engine component of claim 23, wherein said layer thickness of the modified, hydrogen-containing amorphous carbon layer is about 5 μm.

39. The engine component of claim 23, wherein said engine component is in the form of a turbine blade or vane.

40. A jet engine for use in aircraft, characterized in that it has at least one engine component as claimed in claim 23.

41. A process for coating an engine component which is intended to be arranged in the gas flow of a gas turbine, characterized in that a vacuum coating process is used to apply a modified, hydrogen-containing amorphous carbon layer to at least part of the surface of the engine component, which is exposed to the gas flow during operation.

42. The process of claim 41, wherein the hydrogen-containing amorphous carbon layer is modified with at least one non-metal.

43. The process of claim 41, wherein the modified, hydrogen-containing amorphous carbon layer comprises a-C:H:Si and/or a-C:H:Si:O.

44. The process of claim 41, wherein the modified, hydrogen-containing amorphous carbon layer has a hardness of at least 600 HV30.

45. The process of claim 41, wherein the modified, hydrogen-containing amorphous carbon layer has a hardness of at least at least 750 HV30.

46. The process of claim 41, wherein the modified, hydrogen-containing amorphous carbon layer has a hardness of at least at least 900 HV30.

47. The process of claim 41, wherein the modified, hydrogen-containing amorphous carbon layer has a degree of wear of less than 40 (m³/Nm)·10⁻¹⁵.

48. The process of claim 47, wherein the degree of wear is less than 30 (m³/Nm)·10⁻¹⁵.

49. The process of claim 48, wherein the degree of wear is less than 20 (m³/Nm)·10⁻¹⁵.

50. The process of claim 41, wherein the modified, hydrogen-containing amorphous carbon layer has a surface energy of at most 28 mN/m.

51. The process of claim 50, wherein said surface energy is at most 24 mN/m.

52. The process of claim 51, wherein said surface energy is at most 20 mN/m.

53. The process of claim 41, wherein the vacuum coating technique is selected from the group consisting of physical vapor deposition (PVD), chemical vapor deposition (CVD), plasma-assisted physical vapor deposition (PA-PVD) and plasma-assisted chemical vapor deposition (PA-CVD) or a combination thereof.

54. The process of claim 41, wherein the layer thickness of the modified, hydrogen-containing amorphous carbon layer is 2 μm to 10 μm.

55. The process of claim 41, wherein said layer thickness of the modified, hydrogen-containing amorphous carbon layer is 3 μm to 7 μm.

56. The process of claim 41, wherein said layer thickness of the modified, hydrogen-containing amorphous carbon layer is about 5 μm.

57. The process of claim 41, wherein the engine component is in the form of a turbine blade or vane.

58. A process for repairing an engine component which is intended to be arranged in the gas flow of a gas turbine, comprising the following steps:
a) providing an engine component having wear phenomena;
b) working up the engine component in order to eliminate or reduce the wear phenomena; and
c) applying a modified, hydrogen-containing amorphous carbon layer as claimed in claim 41 to at least part of the surface of the engine component that is exposed to the gas flow during operation.

59. The process of claim 58, wherein the engine component is in the form of a turbine blade or vane.

60. The process of claim 59, characterized in that the working-up of the turbine blade or vane involves the production of a defined blade or vane contour.
